(19) United States
(12) Patent Application Publication
(10) Pub. No.: US 2006/0158353 A1
(43) Pub. Date: Jul. 20, 2006

(54) Light guided keyboard system

(76) Inventor: Chiang-Hua Tseng, Taipei City (TW)

Correspondence Address: LEONG C LEI, PMB # 1008, 1867 YGNACIO VALLEY ROAD, WALNUT CREEK, CA, 94598, US

(21) Appl. No.: 11/036,150

(22) Filed: Jan. 18, 2005

(51) Int. Cl. H03M 11/00; H03K 17/94

(52) U.S. Cl. 341/22; 341/31

(57) ABSTRACT

A light guided keyboard system essentially comprised of a light emission circuit and a guide control circuit built in the keyboard; an EL lamp or other light emitting device being connected to the light emission circuit; and guide software such as spelling guide or typing method guide, application software control interface and driver being included in the computer software unit to guide typing of spelling, characters, applications, web pages, game software, and pre-schooling education programs in faster and easier operation of the keyboard.

### BACKGROUND OF THE INVENTION

(a) Technical Field of the Invention

The present invention is related to a light guided keyboard system, and more particularly to one that has the light to guide the next key to be pressed for easier and faster operation of the keyboard.

(b) Description of the Prior Art

To those who are not regulars users or have limited knowledge of computer operation, typing could be a headache; and even to those who are bounded to monitor, they have to be familiar with the location of each key on the keyboard due to the great number of keys thereon before achieving a fast operation either in the input of characters, applications, game software or learning software. Frequent typing errors seriously affect the operation of the computer, and particularly so when various application software and game software are used wherein the instantaneous response is critical to the results of operation. Furthermore, in the keyboard with light emitting function of the prior art, it provides only the function of lighting the key when pressed, and it does not provide any light guided function; and LED generally used as the light emitting device in the prior art is found with defectives including emission of heat at the same time, irritable to the eyes of the user, and shorter service life.

### SUMMARY OF THE INVENTION

The primary purpose of the present invention is to provide a light guided keyboard system to guide the user to press the next key in inputting characters or operating software for achieving faster and easier keyboard operation while minimizing the operation error.

To achieve the purpose, a light emitting circuit and a guide control circuit are built in a keyboard of the prior art; each key is inserted with a light emitting device; a guide software, an application software control interface and driver are installed in the computer software unit to provide light guide to the user to press the next key. Wherein, the light-emitting device inserted in each key relates to an EL lamp or other types of light emitting device. USB port is used in the light guide keyboard system to serve as the HW interface for data transmission and control of the light emitting device.

The light emitting device control circuit is connected in parallel with the existing circuit in the keyboard to drive the light-emitting device in each key

The guide software installed in the present invention provides spelling and input methods (phonetic notation, Chang Jieh, or any other input methods of non-English speaking countries) to guide the user to press the next key

The application software control interface in the present invention provides applications (e.g., game software, learning software, web page programs and other applications) to directly control the light guided keyboard.

The driver in the present invention is provided for driving the light emitting circuit.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a block chart showing the HW and SW configuration of the present invention.

FIG. 2 is a process flow chart of the key operation of the present invention.

FIG. 3 is an exploded view of the construction of a key from the keyboard of the present invention.

FIGS. 4a and 4b are sectional views of keys from the keyboard of the present invention.

FIG. 5 is a schematic view showing various types of light emitting devices used in the present invention.

FIGS. 6A and 6B, 7A and 7B, 8A and 8B, 9A and 9B are schematic views showing a use of the present invention in the operation of spelling.

FIGS. 10 and 11 are schematic views showing another use of the present invention in the operation of applications.

FIG. 12 is a schematic view showing another use yet of the present invention in the operation of logging on a website.

FIG. 13 is a schematic view showing another use yet of the present invention in the operation of game software.

### DETAILED DESCRIPTION OF THE PREFERRED EMBODIMENTS

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

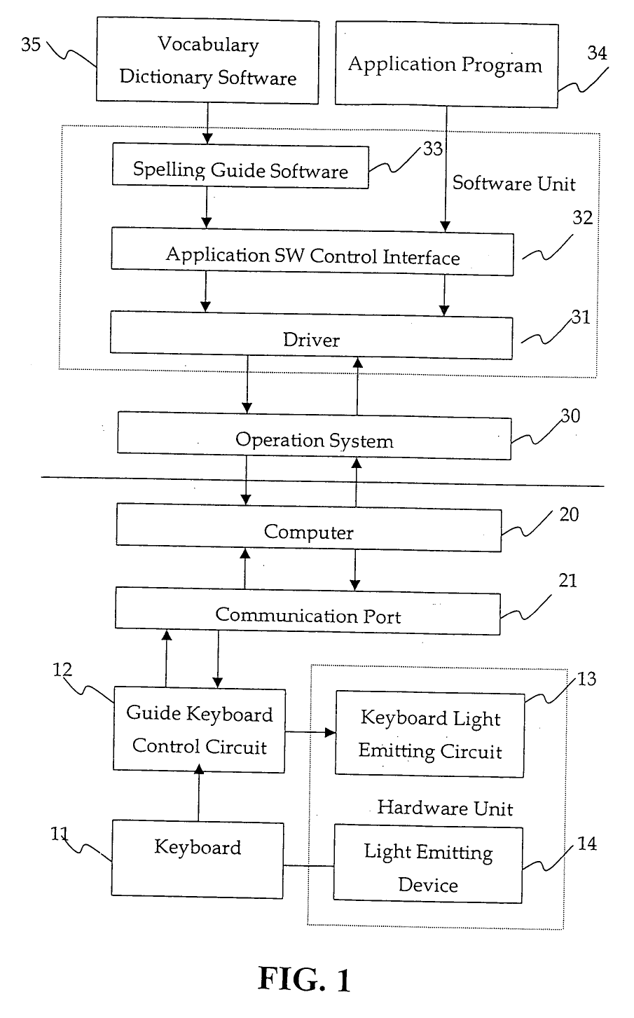

Referring to FIGS. 1, 2, 3, and 4A and 4B, the present invention is essentially comprised of a light guided keyboard control circuit 12 and a keyboard light emitting circuit 13 in a keyboard 11 of the prior art. The light emitting circuit 13 is connected to a light-emitting device 14 in the form of an EL lamp or other light-emitting device (the EL lamp providing advantages of generating no heat, not irritating to eyes, longer service life, and power-saving is used in the preferred embodiment). The assembled keyboard 11 is then connected to a USB port 21 of a computer 20. A driver 31 to drive the light emitting circuit 13, an application software control interface 32, and a spelling guide software 33 are installed in the computer operation system 30 for application programs 34 (e.g., game software, learing software, web page programs, and other application software) or a vocabulary dictionary software 35 (e.g., the dictionary software of vocabulary built-in a language translator) to be enabled with guide function. Accordingly, while operating the keyboard 11, the light emitting device 14 of the key 111 is lighted to guide the user to press the next key by means of the spelling guide software 33, the application software control interface 32 and the driver 31 installed in the computer 20.

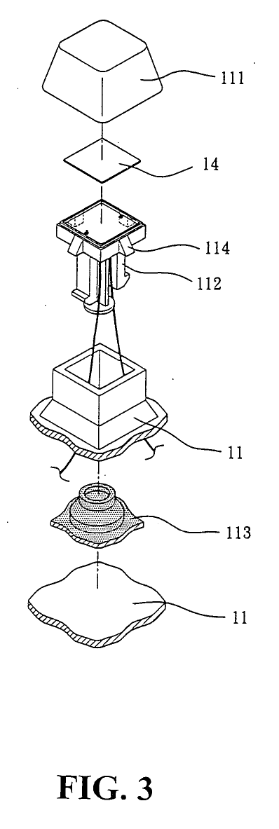

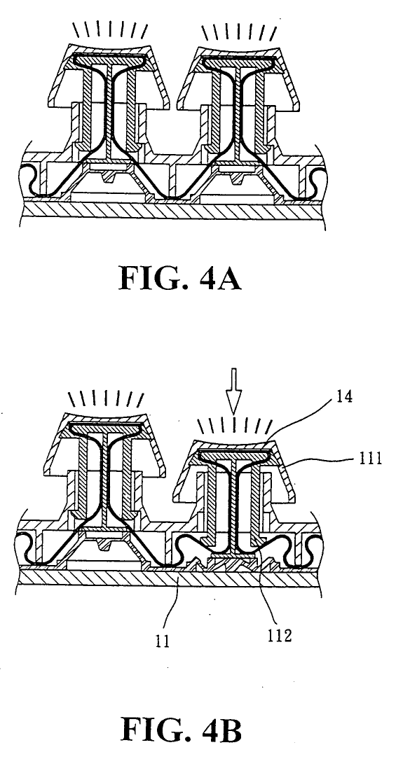

As illustrated in FIGS. 3 and 4A and 4B, the light emitting device 14 is placed below the key 111 so that when lighted the light emitting device 14 upward illuminate the key 111 to guide. A support pillar 112 and an elastic member 113 are provided in the key 11 at where in relation to where the key 111 is located. The support pillar 112 is provided with a rib 114 to be snapped into the key 111 for the key 111 when pressed restores to its original status by taking advantage of the elasticity while allowing easy replacement with other type of the light emitting device 14.

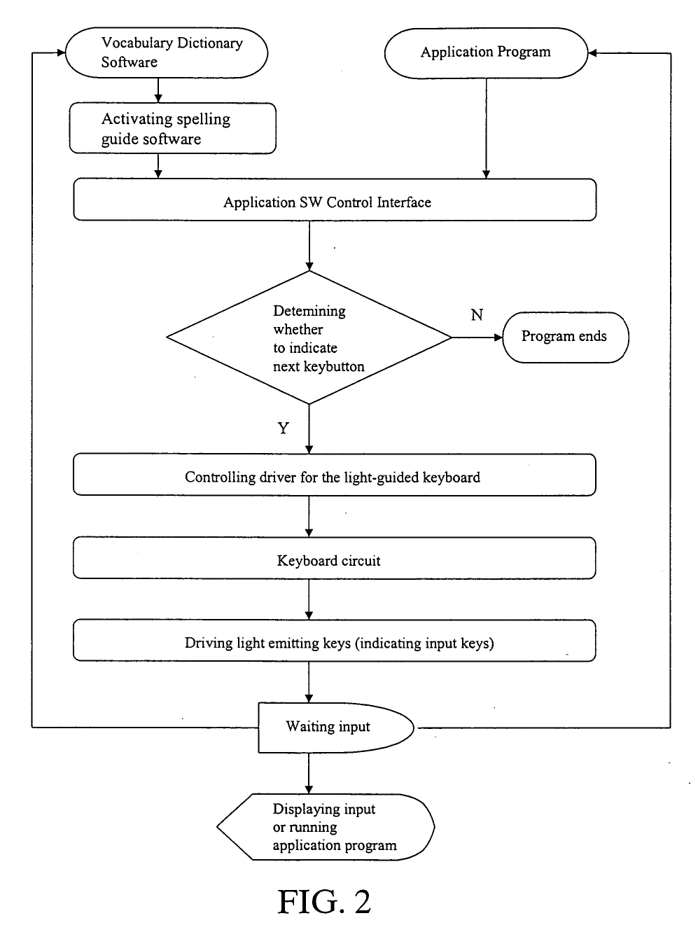

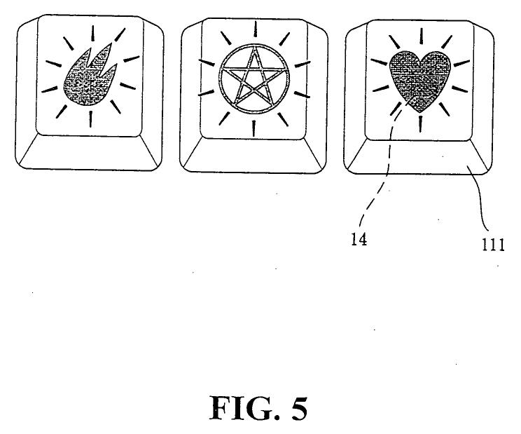

Now referring to FIG. 5, various types of pattern may be given to the light-emitting device 14 for eye-catching advertisement effects while providing the guide to press the next key. As illustrated in FIG. 2, the operation process of the light guided keyboard system of the present invention by compromising different application is described as follows:

1. Spelling guide:
(a) Upon activating the vocabulary dictionary, the spelling guide software is also activated to transmit the location of the next key to be inputted.
(b) Depending on the selection made in Step a, the program provides through the software control interface the location of the key to be illuminated by the driver.
(c) The program will be terminated depending on the judgment made in Step a to see if there is the location to press the key that needs to be illuminated.
(d) The program specifies the key to be illuminated by the light emitting device through the control of the driver of the keyboard and the key specified by the hardware circuit according to the location as indicated in Step a.
(e) The program waits for the user to press the target key to transmit the character to the spelling guide application for making judgment.
(f) The character inputted is displayed.

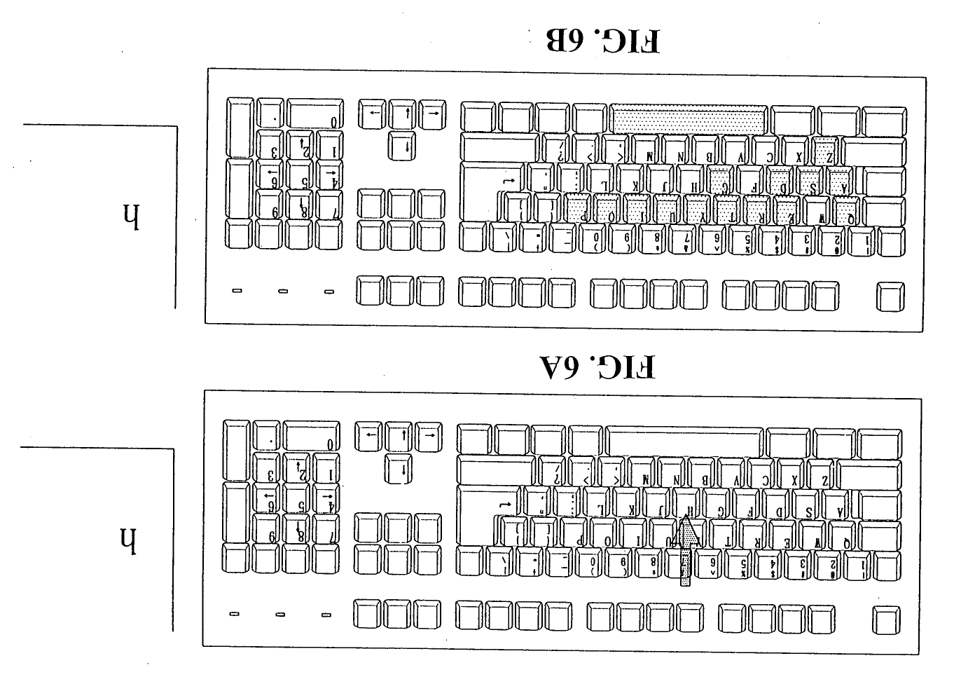

Referring FIGS. 6A, 6B, 7A, 7B, 8A, 8B, 9A and 9B wherein the spelling guide is installed in the preferred embodiment of the present invention.

(a) The user activates the vocabulary dictionary software installed in the computer, and presses H (a in FIGS. 6A and 6B).

(b) All the of keys Q, E, R, T, Y, U, I, O, P, A, S, D, G, Z, and the blank key are illuminated to indicate the next key to press (b in FIGS. 6A and 6B).

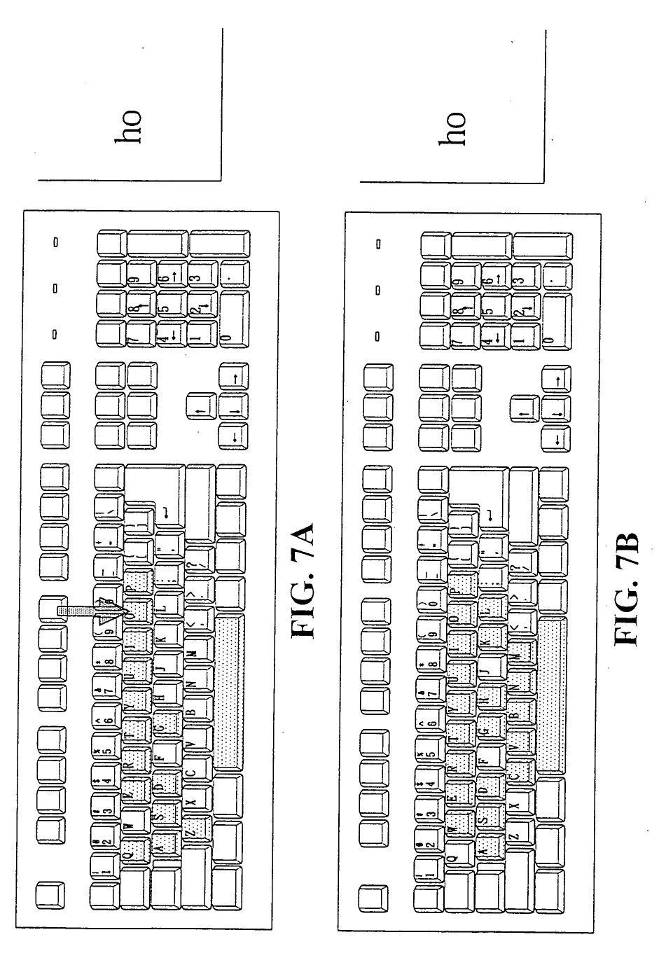

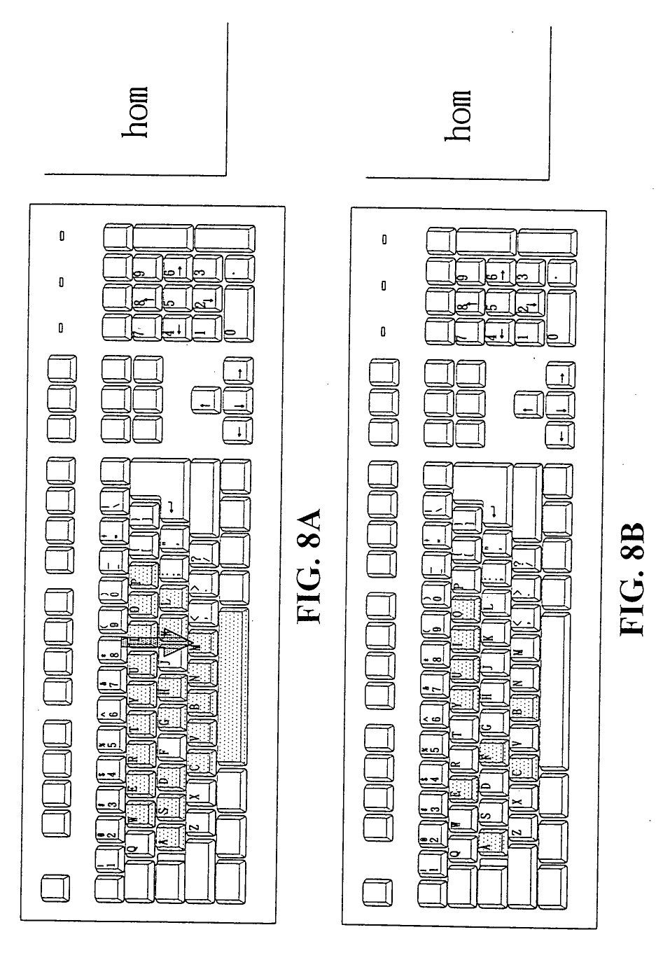

(c) The user presses key O (c in FIGS. 7A and 7B), all the keys of W, E, R, T, Y, U, I, O, P, A, S, D, G, H, K, L, C, V, B, N, M and the blank key are illuminated to indicate the next key to press (d in FIGS. 7A and 7B). The user presses key M (e in FIGS. 8A and 8B), all keys of E, Y, U, I, O, A, F, C, B are illuminated to indicate the next key to press (f in FIGS. 8A and 8B).

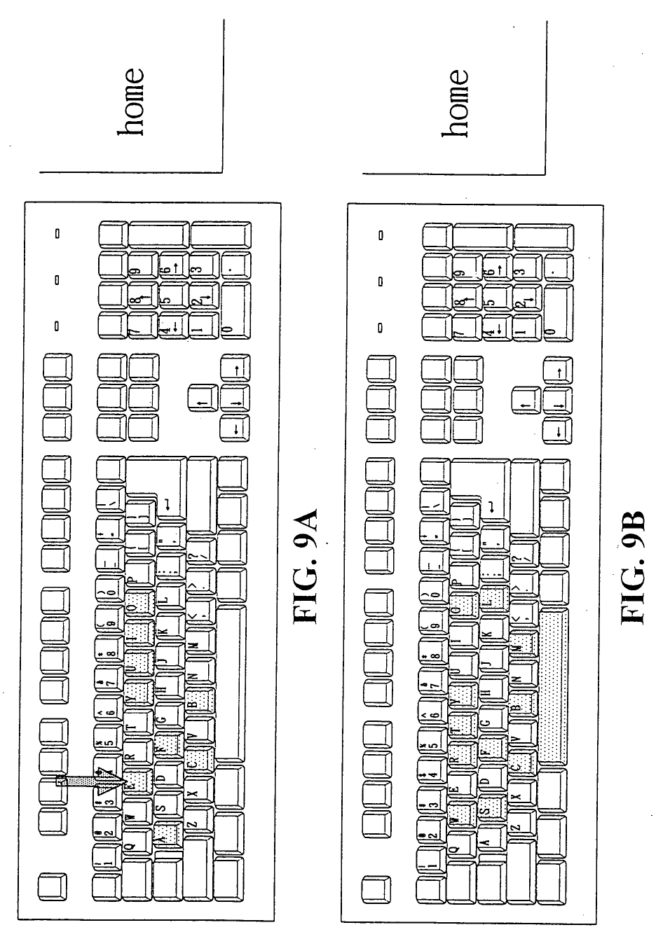

(d) Press key E (g in FIGS. 9A and 9B), all the keys of W, R, T, Y, O, S, F, L, C, B, M and the blank key are illuminated, and the blank key is selected to complete the input and all illuminated keys are off (not illustrated).

Preferred embodiments given above are for facilitating the description. It should be appreciated that the software of the vocabulary dictionary and the spelling guide may vary (e.g., the phonetic notation, Chang Jieh, or any other input methods of non-English speaking countries) depending on the particularly spelling or input method of a particular area.

2. Applications guide (e.g., game software, learning software, web page, and other application software) operates as follows:
(a) In the course of developing applications, the program can be used to directly control the location of the key to be illuminated through the software interface.
(b) Depending on the location to be illuminated as described in Step a, the program determines if there is the location of the key to be illuminated. If not, the program is terminated.
(c) If there is the key to be driven, the light-emitting device is lighted through the control of the driver of the keyboard and the key specified by the hardware circuit.
(d) The program awaits the input of the key by the user to respond the message to the application software.
(e) The character inputted or the application executed is displayed.

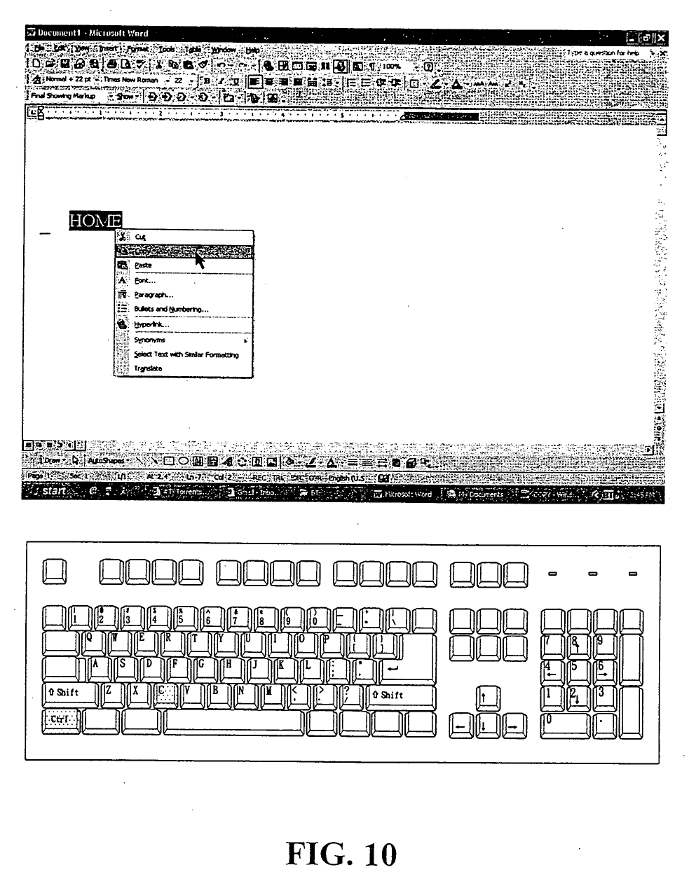

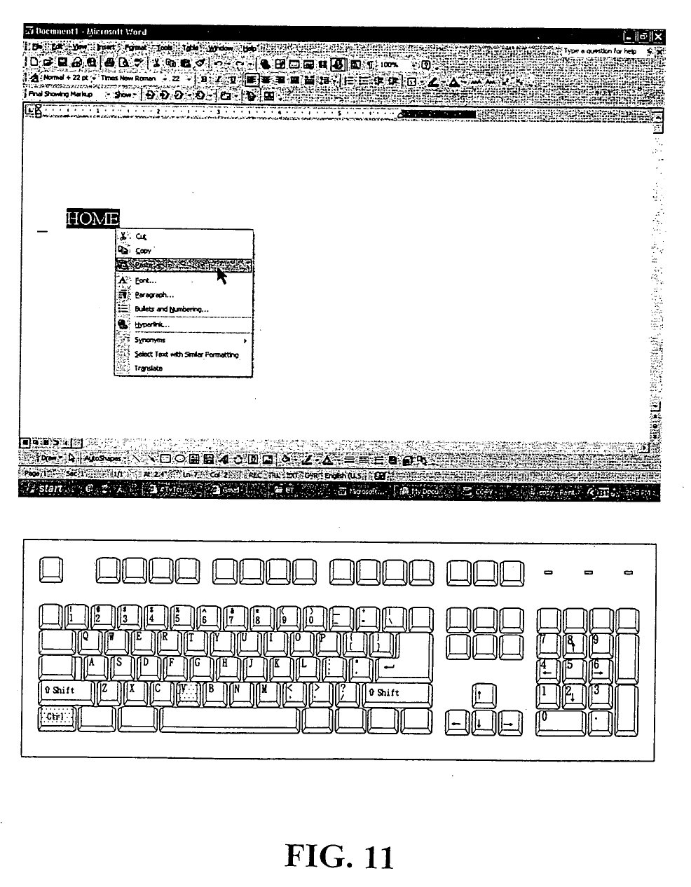

As illustrated in FIGS. 10 and 11, wherein the present invention is used in application software such as Word. With the mouse to click on “Copy”, both keys of Ctr1 and C are illuminated to indicate that both keys are fast keys to execute the command of Copy. When the mouse clicks on “Paste”, both keys of Ctr1 and V are illuminated to represent that both keys should be pressed at the same time to execute the command of Paste.

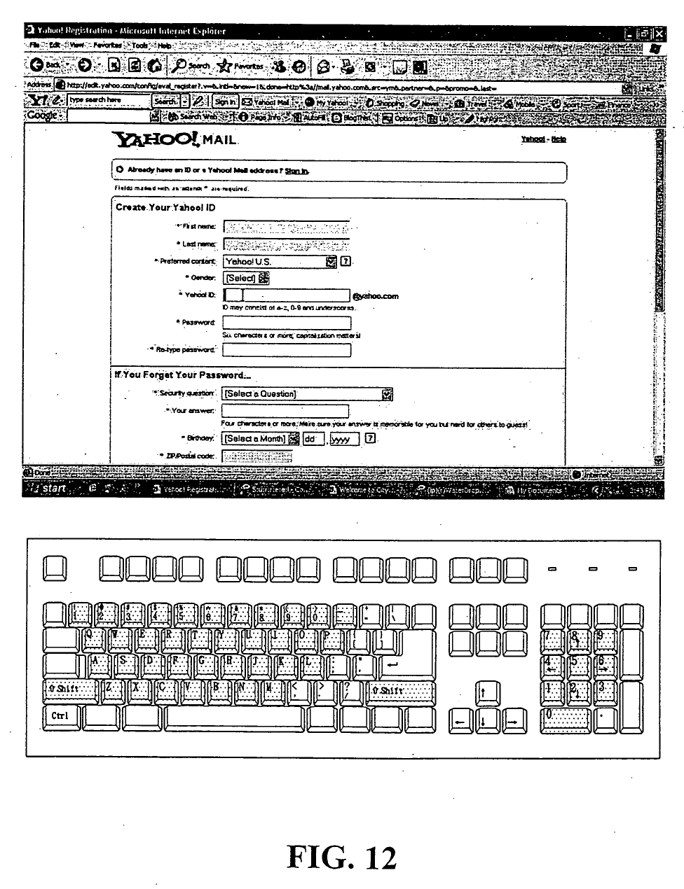

Also referring to FIG. 12, when the present invention is applied in logging on a website and the mouse clicks on ID, keys related to that column and available for input are illuminated for typing. When Password is clicked, keys related to that column and available for input are illuminated for typing. If the page instructs to fill in personal particulars (not illustrated) and “Tel. No.” is selected, all the numeric keys are illuminated pending for the next input (since only the numbers are needed to be inputted in case of a telephone number).

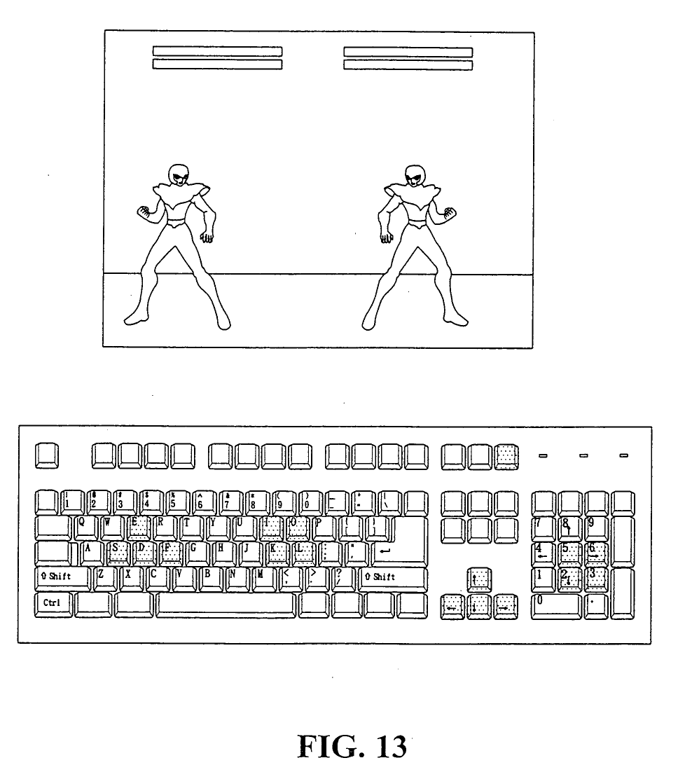

As illustrated in FIG. 13, the present invention may be applied in the operation and control of game software. In playing the game, the corresponding key will be illuminated. Similarly, the present invention also provides the effects of illuminating the corresponding keys in the use of learning software.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A light guided keyboard system includes a light-emitting circuit and a guide control circuit; a light-emitting device being inserted in each key on the keyboard; each light-emitting device being connected to the light-emitting circuit; guide software, application software control interface, and driver being installed in the computer software unit; and one or multiple light-emitting devices being illuminated during the operation of the keyboard through the control of guide software, application software control interface, and driver depending on the spelling method or the application software or web page input to guide the user the next key to be inputted by illuminating that key.

2. The light guided keyboard system of claim 1, wherein the light-emitting device provided in the key relates to an EL lamp or any other type of light emitting device.

3. The light guided keyboard system of claim 1, wherein the guide keyboard control circuit is coupled to the keyboard circuit connected by USB.

4. The light guided keyboard system of claim 1, wherein the guide software provides the data needed in spelling judgment and spelling guide to indicate the location of the next key to be pressed.

5. The light guided keyboard system of claim 1, wherein the application software control interface provided for the application software and spelling guide software is related to the interface program to control the key to be illuminated.

6. The light guided keyboard system of claim 1, wherein the driver is used to drive the light emitting circuit of the keyboard.

7. The light guided keyboard system of claim 1, wherein the surface of the light-emitting device can be made in various patterns.
